(19) United States
(12) Patent Application Publication
(10) Pub. No.: US 2009/0032949 A1
(43) Pub. Date: Feb. 5, 2009

(54) Method of depositing Tungsten using plasma-treated tungsten nitride

(75) Inventor: Jaydeb Goswami, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/890,192

(22) Filed: Aug. 2, 2007

(51) Int. Cl. H01L 23/48; H01L 21/4763

(52) U.S. Cl. 257/741; 438/618; 257/E23.01; 257/E21.495

(57) ABSTRACT

Devices structures utilizing, and methods of forming, tungsten interconnects in semiconductor fabrication are disclosed. Tungsten deposition is accomplished by a three-step process that does not require a resistive nucleation material to be deposited prior to bulk tungsten deposition. By treating a tungsten nitride material with a hydrogen plasma, thereby reducing the tungsten nitride to tungsten, the necessity of a resistive nucleation layer is eliminated. Other embodiments describe methods of tungsten deposition requiring a thinner resistive nucleation material (<10 angstroms) than currently known.

### FIELD OF THE INVENTION

This disclosure relates generally to integrated circuits and, more particularly, to the deposition of tungsten for interconnect structures.

### BACKGROUND OF THE INVENTION

As the semiconductor industry continues to increase the density of devices, it has become necessary to manufacture integrated circuits (IC) continuously smaller and with denser feature profiles. It is necessary, therefore, that the constituent features that form the integrated circuit, e.g., interconnect lines and electrical devices, also continue to decrease in size to accommodate these continuing demands.

A semiconductor device generally includes a semiconductor substrate, typically consisting of silicon, and sequentially formed layers such as insulators, semi-conductive and conductive material to form electrical structures and conductive paths or interconnects. It is desirable to form interconnects in certain areas of dielectric or insulating materials to electrically connect device structures such as source/drain regions of a transistor. IC interconnects can be formed by depositing a conductive material, e.g., copper, aluminum or tungsten, within an opening or via etched into an insulating material or directly over the insulating material, for example during the formation of a bitline structure in memory devices such as NAND or DRAM.

There are several materials which may be used to form electrical connections in IC fabrication. These can include aluminum, copper and tungsten, among others. Although tungsten has a higher resistivity than other conductive materials used, generally interconnects are formed with tungsten because of several advantages. Unlike copper, which requires barrier layers to prevent migration of copper atoms into the silicon or other layers resulting in contamination, tungsten tends not to migrate. Additionally, tungsten can be deposited via thermal chemical vapor deposition (CVD). Aluminum and copper must be sputtered or electroplated onto the substrate, at an increased manufacturing cost.

Tungsten may be deposited using thermal CVD methods normally involving the reduction of tungsten hexafluoride (WF6) by hydrogen (H2) or silane (SiH4). However, an inherent difficulty of this deposition process is getting tungsten to begin to deposit on a substrate, as tungsten does not adhere well to common dielectric materials. The deposition of a resistive adhesion layer, for example titanium nitride or tungsten nitride, prior to the CVD deposition of tungsten is one method of improving adhesion of tungsten to insulating materials.

FIGS. 1A-1C are cross-sectional views illustrating a conventional method for depositing tungsten utilizing a resistive nucleation material on a non-planar structure, for example in a NAND device. It should be understood to one skilled in the art that the process steps described in FIGS. 1A-1C can be applicable to the formation of planar structures as well as non-planar structures. Referring to FIGS. 1A-C, a structure which includes a silicon dioxide 10 deposited on a substrate which includes a via or trench 20 formed within the silicon dioxide is illustrated. A nitride material 30, for example tungsten nitride, is deposited over the silicon dioxide 10, followed by the deposition of a resistive tungsten nucleation material 40. To improve nucleation of subsequent bulk tungsten deposition, a resistive tungsten nucleation material is formed to a thickness of from about 100 to about 200 angstroms. Bulk tungsten 50 is then deposited by methods known in the art, for instance by a thermal CVD process. A similar process can be used for the deposition of a resistive nucleation material on a planar structure, such as in DRAM device fabrication.

The resistive nucleation material provides for regions of growth sites allowing for tungsten to deposit more robustly. However, as the critical dimensions of interconnect structures decrease, this requirement for a thick nucleation material causes line resistivity to increase. In NAND devices, this increase in resistivity is the result of a decreased amount of bulk tungsten able to be deposited because the resistive nucleation material takes up a greater percentage of the available volume of the interconnect structure. In DRAM devices, the increase in resistivity is a result of an increase in total structure height due to the necessity of resistive nucleation material.

Interconnects, such as bitlines, have internal resistance, internal parasitic capacitance and parasitic capacitance with other interconnects. The resistance and capacitance comprise an RC circuit whose time constant increases the equalization time for pre-charging the bitlines. If too large, the time constant results in a slower read time for the memory device that limits the use of the memory device in modern high-speed electronics. As clock speeds for memory devices increase, the minimum time between commands lessens and the equalization times for bitlines should also decrease.

Decreasing interconnect resistance/capacitance can improve write and read performance and failure rates. The capacitance can be decreased by reducing interconnect thickness. However, a decrease in line thickness below 1,000 angstroms significantly increases resistivity, resulting in degradation of device performance.

Accordingly, there is a need for improved methods for the deposition of tungsten in interconnect structures to decrease resistivity.

### BRIEF DESCRIPTION OF THE DRAWINGS

FIGS. 1A-1C depict a sequence of process steps of a prior art bulk tungsten deposition.

FIG. 2 is a top plan view depicting an in-process semiconductor wafer having partially etched grooves according to embodiments of the invention.

FIG. 3 illustrates a multi-step process sequence for tungsten deposition utilizing deposition techniques according to embodiments of the invention.

FIG. 4 illustrates a process sequence for deposition of resistive tungsten nucleation material and bulk tungsten utilizing a sequential chemical vapor deposition (CVD) technique according to embodiments of the invention.

FIGS. 5-8 show a schematic cross-sectional view of part of an in-process semiconducting substrate at successive stages in a method of tungsten deposition according to embodiments of the invention.

FIGS. 9-10 shows a schematic cross-sectional view of part of an in-process semiconducting substrate at successive stages in a method of tungsten deposition utilizing a resistive nucleation material according to embodiments of the invention.

FIG. 11 shows a schematic cross-sectional view of part of an in-process semiconducting substrate at successive stages in a method of tungsten deposition without utilization of a resistive nucleation material according to embodiments of the invention.

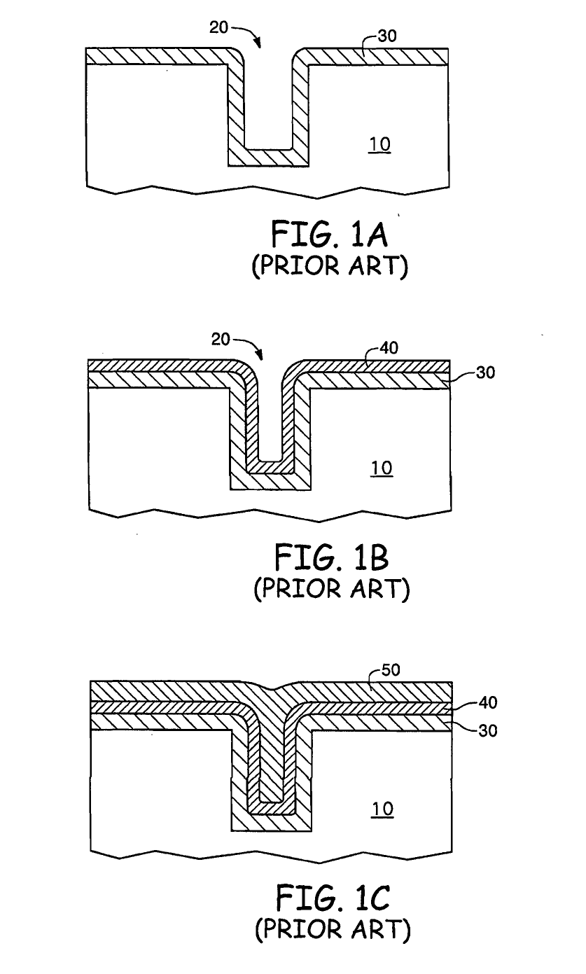

It should be emphasized that the drawings herein may not be to exact scale and are schematic representations. The drawings are not intended to portray the specific parameters, materials, particular uses, or the structural detail embodiments of the invention.

### DETAILED DESCRIPTION OF THE ILLUSTRATED EMBODIMENTS

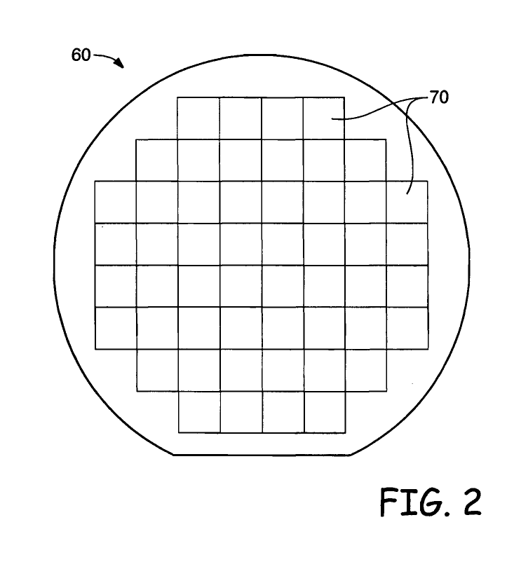

With reference to FIG. 2, during the semiconductor manufacturing process, components are formed in/on an in-process semiconductive wafer or substrate 60. Such processing results in the formation of various structures of an integrated circuit (IC). This is accomplished through the formation of multiple material layers comprising insulative, conductive and semi-conductive materials. Material layers are incorporated in/on the substrate through the use of several processing techniques including, but not limited to, doping, deposition and etching. In general, integrated circuits are produced in large batches on a single wafer. Following the formation of the IC on the wafer, the water is cut into a plurality of pieces 70 (singulation), each such piece containing one copy of the integrated circuit being produced. Each piece separated from the wafer is known as a die or dice and comprises a small substrate of semiconducting material upon which a given functional circuit is fabricated. Each die can be a memory device, an application-specific integrated circuit (ASIC), a system-on-a-chip, a processor, an imager or other type of IC. Once the various semiconductor structures have been formed on each die, they are connected via conductive features (interconnects) to form electrical circuits. Interconnects can be deposited or plated and can comprise, for example, copper, aluminum or tungsten.

Embodiments of the present invention describe methods for depositing tungsten (W) for use as an interconnect material in integrated circuits, such as memory devices. According to an embodiment of the present invention, CVD tungsten deposition occurs without the necessity of a resistive nucleation layer deposition. In another embodiment of the present invention, a thin (about 5 to 10 angstroms) resistive nucleation layer may be created prior to thermal chemical vapor deposition (CVD) of bulk tungsten.

As used herein, the terms “semiconductor substrate,” “substrate” or “wafer” are interchangeable and are understood as including silicon, silicon-on-insulator (SOI), or silicon-on-sapphire (SOS) technology, doped and undoped semiconductors, epitaxial layers of silicon supported by a base semiconductor foundation, and other semiconductor structures. Furthermore, when reference is made to a “semiconductor substrate,” “substrate” or “wafer” in the following description, previous process steps may have been utilized to form regions or junctions within or on the base semiconductor structure or foundation. In addition, the semiconductor need not be silicon-based, but could be based on semiconductors including silicon-germanium, germanium, or gallium-arsenide. Further, the term “about” indicates that the value listed may be somewhat altered, as long as the alteration does not result in nonconformance of the process or structure in question to the illustrated embodiment of the present invention.

Additionally, the terms “conformal” or “uniform” generally refer to a ratio of horizontal surface film thickness to vertical surface film thickness during a deposition process. As a reference, a deposition process that is perfectly conformal will have about a 1:1 ratio of horizontal surface film thickness to vertical surface film thickness. That is, the film will be deposited on horizontal surfaces at the same rate that the film is deposited on vertical surfaces.

Also, as used herein, “interconnect(s),” “interconnect structure(s),” or “interconnect lines” are interchangeable and generally refer to electrical connections (conductive structures) between two or more areas of an integrated circuit, or between multiple integrated circuits, which allow for the flow of elections. Such electrical connections can be planar or non-planar and may include metal transmission lines or filled trenches or vias. Further, as used herein, “interconnect(s),” “interconnect structure(s),” or “interconnect lines” includes, but is not limited to, metal or alloy and may include but not be limited to, aluminum, tungsten, copper or polysilicon.

The methods, processes and semiconductive structures described herein do not form a complete flow for the fabrication of semiconductive devices. Process and process flows not described in detail herein are known to those skilled in the art and only those processes and flows necessary to the understanding of the described embodiments of the present invention are herein described.

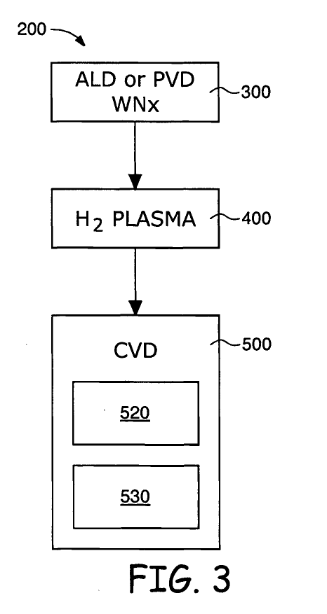

FIG. 3 illustrates a multi-step process sequence 200 for tungsten deposition according to embodiments of the present invention. An in-process semiconductor substrate is subjected to the multi-step process 200 which includes an atomic layer deposition (ALD) or physical vapor deposition (PVD) step 300, a hydrogen plasma step 400, and a chemical vapor deposition (CVD) step 500. A tungsten nitride (WNx) material is deposited via ALD or PVD on a substrate during step 300, for example during memory device fabrication. The WNx material can function as a barrier layer to minimize migration of undesirable material, for example atoms or ions, or to promote adhesion of bulk W deposited during subsequent processing steps. Following deposition, the WNx is then subjected to a hydrogen plasma treatment, at step 400, resulting in the reduction of at least a portion of the WNx to tungsten (W). This reduction results in at least a partial denuding of the WNx of nitrogen. Subsequently, the in-process substrate can be subjected to a thermal tungsten CVD process step 500 resulting in the deposition of a W material. Thermal CVD process step 500 can be accomplished via a two substep process, utilizing substeps 520 and 530, or through a single substep process, utilizing only substep 530. In one embodiment, an optional resistive nucleation material is deposited during substep 520 prior to the deposition of bulk W during substep 530. Alternatively, in another embodiment, CVD process 500 can comprise only substep 530, in which no W nucleation material is required prior to the bulk deposition of W.

Referencing FIG. 3, during the first operational step 300 of the disclosed multi-step process sequence 200, an in-process semiconductor comprising at least a dielectric material, such as an oxide, is subjected to an ALD or PVD process. The substrate surface can be planar, e.g. as in a DRAM memory device, or non-planar, e.g. as in a NAND memory device, and may comprise a feature in the dielectric material where an interconnect structure will be formed, such as a trench or via. During process step 300, a WNx material is deposited on the substrate adjacent to at least a portion of a dielectric or oxide material. The deposition of the WNx material by either ALD or PVD in process step 300 is performed by methods known in the art and available to the skilled practioner. For example, if an ALD process is utilized in the fabrication process, it can be a sequential deposition process comprising multiple cycles, each one cycle comprising three phases. Each one cycle may deposit up to about 1 angstrom of WNx. Following each cycle of process step 300, if the desired thickness of WNx has been achieved, the process is terminated. If the desired thickness has not been achieved, the process is repeated until the desired thickness is achieved. WNx thickness is dependent on the structure being fabricated. Additionally, ALD allows for superior step coverage and greater control of material thickness during deposition. The ALD process allows for a conformal deposition of WNx such that conformality of the deposited material allows for better control of feature fill as IC feature size continues to decrease. Also, this conformality of the ALD-deposited material is independent of pattern loading effect, i.e., it is not dependent on the density of features.

With continued reference to FIG. 3, following the process step 300, the second operational step, hydrogen plasma step 400, of the multi-step sequence 200 is performed. The substrate is removed from the deposition tool and placed into a single wafer plasma chamber. In accordance with embodiments of the invention, the exposed WNx surface of the substrate is subjected to a hydrogen plasma treatment. Hydrogen gas is flowed into the chamber and subjected to a plasma arc. Depending on the time period of exposure, all or some of the WNx deposited during step 300 is denuded of nitrogen, thereby converting WNx to W. The hydrogen plasma treatment process 400 leaves a W material exposed at least at the surface of substrate 110 and NH3 gas as a byproduct of the reaction.

The plasma power may be radio frequency (RF), microwave or remote plasma, with RF being more effective. The plasma is applied at a power level range of from about 300 to 1000 watts, with a power level of about 800 watts being useful. The plasma power level is applied for a time period of from about 10 to 1000 seconds, with a plasma application of about 60 seconds being of use. Temperature within the chamber is maintained in a range between about 500 to 850 degrees C., with a useful effective temperature of about 650 degrees C. The chamber is maintained at a pressure of from about 10 mTorr to 100 Torr, with a pressure of 5 Torr being effective.

With continued reference to FIG. 3, following the hydrogen plasma step 400 of the multi-step sequence 200, thermal CVD process step 500 can be performed to deposit W material. Such deposition can be performed by methods known in the art available to the skilled practioner. W-CVD process step 500 can be preformed either in a conventional two substep CVD process utilizing process sequence substeps 520 and 530, in which an optional resistive nucleation material (step 520) is deposited prior to bulk W deposition (step 530); or as a single substep process in which no nucleation material is deposited prior to bulk W deposition (step 530).

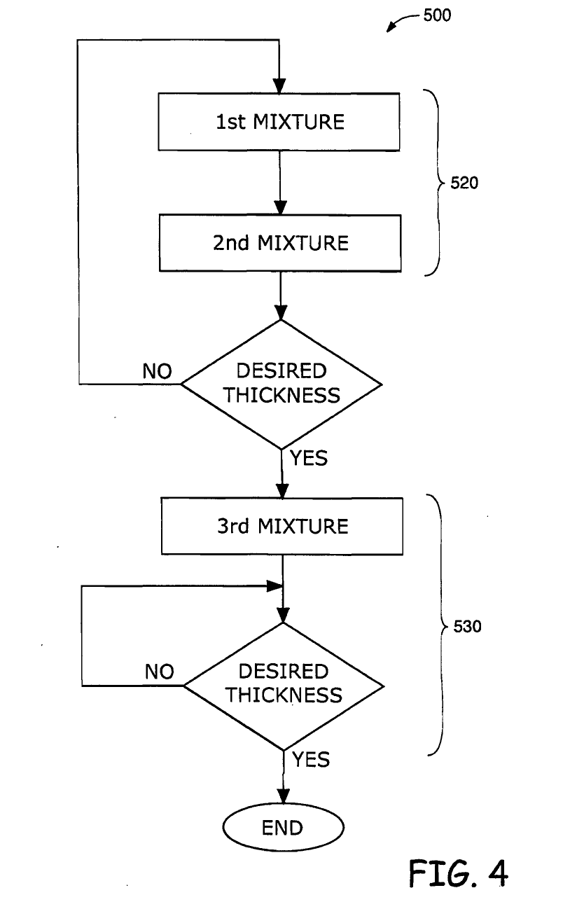

In one embodiment of the present invention as shown in FIG. 4, a two substep method of depositing a tungsten material is illustrated. W is deposited through the sequential deposition of an optional W resistive nucleation material, followed by bulk W deposition. The resistive nucleation material may be formed through the sequential reduction of tungsten hexafluoride (WF6) by silane (SiH4) or diborane (B2H6) by process known in the art. FIG. 4 illustrates the W-CVD deposition process. A first mixture comprising a carrier gas and reactant gas, followed by a second mixture comprising a carrier gas and a second reactant is established in a reaction chamber. Each cycle of first mixture followed by second mixture of can be from about 2 to 15 seconds, with a cycle time of about 3.5 seconds being useful. Additionally, each cycle deposits approximately 5 angstroms of resistive nucleation material. The thickness for the resistive nucleation material can be from about 1 to 25 angstroms, with about 10 angstroms being useful. Therefore, from about one to two cycles is of use. Once the desired thickness of resistive nucleation material is reached, the process is stopped and the deposition of bulk W occurs.

Bulk W deposition is accomplished through methods known in the art, and illustrated in step 530 as shown in FIG. 4. The in-process semiconductor substrate comprising the optional resistive nucleation material is exposed to a third mixture 525 comprising a third CVD reactant gas and carrier gas. Third mixture remains in contact with the substrate surface until the desired thickness of W is achieved. The deposition of bulk W thickness is time variable and dependent on the device structure to be fabricated. For example, for planar surfaces, a time of about 10 to 50 seconds, with a time of about 30 seconds as being most useful. For non-planar surfaces, a time of about 10 seconds to about 1000 seconds, with a time of from about 170 seconds to about 210 seconds being useful. In one embodiment, bulk W thickness on a planar surface can be from about 400 angstroms and on a non-planar surface be from about 2500 angstroms.

With continued reference to FIG. 4, in another embodiment, a W-CVD method for depositing a tungsten material without deposition of optional resistive nucleation material via process step 520 is described. WNx converted to W (conversion material) during hydrogen plasma step 400 is subjected to the thermal CVD process as described above for bulk W deposition (process step 530). The conversion material created during hydrogen plasma step provides sufficient adhesion area for W deposition to occur. Once the desired bulk W thickness is achieved, the process is stopped. The ability to deposit W without the necessity of a resistive nucleation material enables a decrease in line resistivity through the increase in the amount of bulk W present within the interconnect. Deposition time frames and W material thickness is similar to that described above for bulk W deposition utilizing a resistive nucleation material.

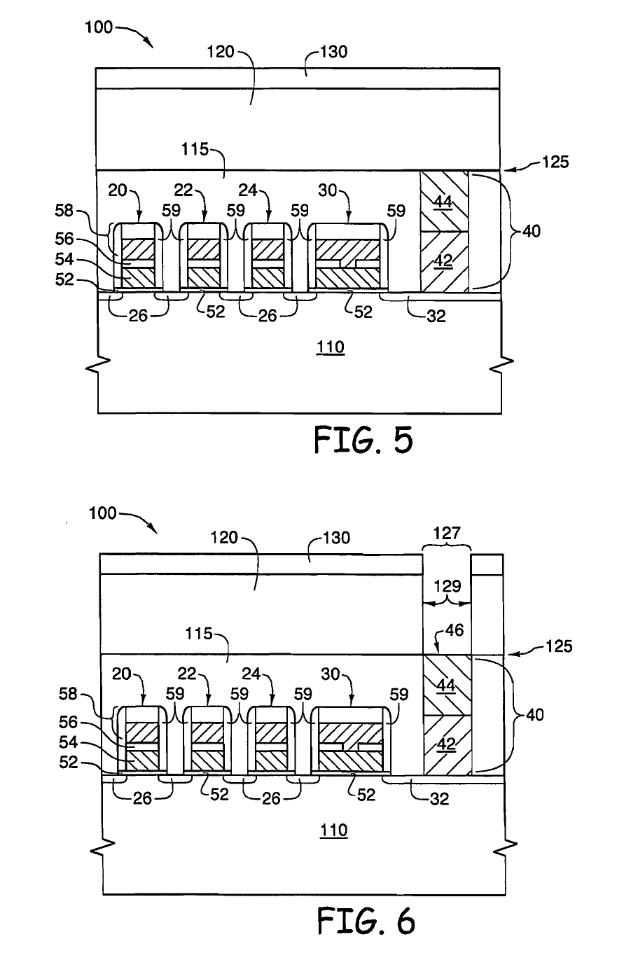

FIG. 5 illustrates a cross-sectional view of an in-process semiconductor 100, for example a NAND flash memory device, of an embodiment of the present invention. Structures of the in-process integrated circuit are depicted in, on or above substrate 110. Although this embodiment may be formed using methods described herein with reference to a portion of a NAND flash memory array, it will be understood by those skilled in the art that the methods described for tungsten deposition for anon-planar structure can be applicable for any type of semiconductor device fabrication requiring interconnect structures, for example DRAM memory devices and C-MOS imagers. While a NAND device will contain more features than shown in the following figures, a redacted device is shown for illustrative purposes only.

With continued reference to FIG. 5, a portion of an in-process semiconductor 100, includes a semiconductor substrate 110 having a plurality of transistor gates 20, 22, and 24; a plurality of source/drain regions 26; a select gate drain structure 30; a select gate drain region 32 and a bitline contact 40 on, above or within the semiconductor substrate 110 is shown. The transistor gates 20, 22, and 24 include a gate oxide 52; a floating gate 54; a gate dielectric 56; a control gate 58; and sidewall spacers 59. Select gate drain structure 30 comprises similar construction as transistor gates 20, 22, and 24. However, where the gate dielectric 56 is substantially continuous across the transistor structure, gate dielectric 56 is discontinuous within the select gate drain structure 30. As used in this disclosure, continuous means a material is uninterrupted within a structure. Further, as used in this disclosure, discontinuous identifies a material that is interrupted within a structure.

A first oxide containing material 115 is shown deposited adjacent to and above transistor gates 20, 22, and 24 and select gate drain structure 30. First oxide containing material may consist of borophosphosilicate glass (BPSG), but may consist of silicon dioxide (SiO2) or spin-on-dielectric (SOD). The first oxide containing material 115 may include a single homogeneous material as shown, or it may comprise multiple layers. First oxide containing material 115 can function as a barrier layer to prevent migration of undesirable materials, such as ions, during further processing. Additionally, first oxide containing material 115 can function as an insulator, isolating other conductive materials (not shown) from subsequently fabricated conductive materials, such as higher level interconnects. First oxide containing material 115 may have a thickness of from about 5,000 to about 20,000 angstroms and be formed by processes known in the art. For instance, first oxide material may be deposited by CVD, SOD or other deposition methods. A bitline contact plug 40 is formed within the first oxide containing material through methods know in the art. The bitline contact plug 40 comprises, for example, a polysilicon plug 42 formed in contact with at least a portion of substrate 110 and a conductive plug 44 formed in alignment and in contact with at least a portion of polysilicon plug 42. The bitline contact plug 40 is contained within, and is co-planar with, first oxide containing material 115. A second oxide containing material 120 is deposited atop and in contact with at least a portion of first oxide containing material 115 and bitline plug 40 through methods known in the art. For instance, second oxide containing material may be deposited via CVD or through other known deposition techniques. The second oxide containing material may consist of BPSG, but may also consist of SiO2 or SOD and may have a thickness of from about 1,000 to about 10,000 angstroms. First oxide containing material and second oxide containing material may be present in device 100 as the same or different materials. Second oxide containing material 120 contacts at least a portion of first oxide containing material 115 forming a first oxide containing material˜second oxide containing material junction 125 which is co-planar with upper surface of bitline contact plug 40. A nitride containing material 130 is deposited atop the insulating material 120 utilizing known methods and may have a thickness of from about 100 to about 1,000 angstroms. Nitride containing material 130 may consist of silicon nitride and may function as a barrier to diffusion of undesirable materials during subsequent processing.

Referring to FIG. 6, an interconnect structure opening 127 which may expose a conductive region or structure is formed extending vertically downward towards substrate 110 through techniques known in the art, including photomasking and etching techniques. Interconnect structure opening 127 traverses nitride material 130, and second oxide containing material 120, and extends downward towards the first oxide containing material˜second oxide containing material junction 125, creating side-walls 129. Such sidewalls 129 may be defined completely or partially within second oxide containing material. Interconnect structure opening 127 may also be formed in alignment with, and may expose and contact at least a portion of bitline contact plug 40, such as upper surface 46. The width of interconnect contact opening 127 may be from about 20 to about 50 nm. Interconnect structure opening 127 may be defined completely or partially within second oxide containing material 120, or also completely or partially within oxide material 115. Furthermore, interconnect opening 127 may be defined completely or partially within substrate 100 itself when oxide containing material is formed at least partially in contact with the substrate. In one embodiment interconnect structure opening 127 may extend to about the first oxide containing material˜second oxide containing material junction 125 and in alignment with bitline contact plug 40, the process of forming bit line contact opening 40 resulting in exposing the upper surface 46 of conductive plug 40. Additional interconnect features may also of course be fabricated relative to the identified device 100, with only one being shown for clarity and simplicity.

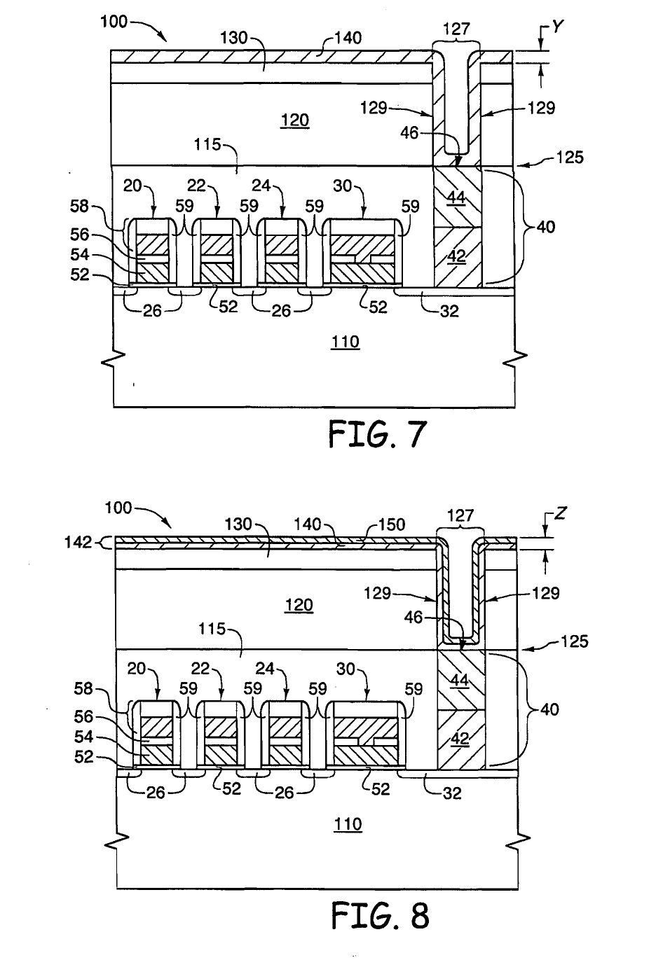

Referring now to FIG. 7 and in accordance with the process steps described above with reference to FIG. 3, a WNx material 140 is deposited via ALD or PVD in process step 300. As a result of this step 300 (for example that described for ALD deposition in NAND memory device fabrication), a WNx material 140 is deposited on nitride material 130 and within interconnect structure opening 127 such that sidewalls 129 and upper surface 46 of bitline contact plug 40 are at least partially in contact with the WNx material 140. WNx material thickness “y” is from about 10 to 60 angstroms, with a thickness of from about 45 to about 50 angstroms being useful. Deposition of WNx material 140 may act as an adhesion layer to promote bonding of W material to substrate 110 during subsequent processing steps. Additionally, WNx material 140 may act as a barrier to diffusion of undesirable materials during subsequent processing.

Following WNx material 140 deposition, and with reference to FIGS. 3 and 8, in-process semiconductor 100 is removed from the ALD deposition chamber and placed into a single-wafer plasma chamber and subjected to a hydrogen plasma treatment 400 as described above. During the hydrogen treatment step 400, WNx material 140 is denuded of nitrogen, converting at least a portion of the WNx material to a conversion material 150, consisting of an upwardly extending W layer and a downwardly extending WNx layer (material 140 is now 142). Although all of the WNx 140 may be denuded of nitrogen and converted to W during the hydrogen plasma treatment process, such total conversion may result in an undesirable loss of the WNx barrier layer. Therefore, conversion of some portion of less than the total WNx deposited is more useful. For example, a conversion of from about 10 to 100 percent of the WNx, with a more effective WNx conversion of about 90 percent, is useful. As will be appreciated, because no further material deposition has occurred during the hydrogen plasma step 400 of multi-step process 200, the thickness “z” of WNx 140 and conversion material 150 (together material 142) is about equal to that of thickness “y” of WNx 140, where material 140 is from about 0 to about 50 angstroms with 5 angstroms being useful and conversion material 150 is from about 10 to 60 angstroms, with 45 angstroms being useful.

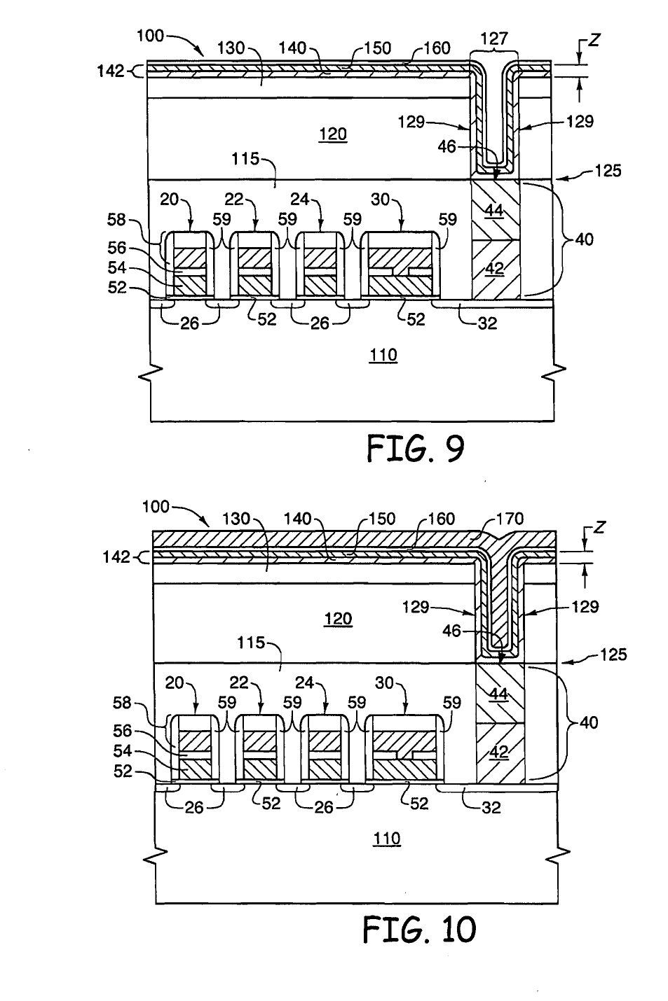

With reference to FIGS. 4 and 9, and in one embodiment of the invention, in-process semiconductor 100 is removed from the single wafer plasma chamber, placed into a CVD deposition chamber and subjected to a two substep W-CVD process as described above in process step 500. A resistive nucleation material 160 is formed overlying conversion material 150; including the surfaces of conversion material 150 deposited within interconnect structure 127. During the nucleation step 520, WF6 is chemically reduced by SiH4 gas resulting in the deposition of a resistive W nucleation material 160. The thickness for the resistive nucleation material 160 is variable depending on the device structure to be fabricated. However, material thickness can be from about 1 to 25 angstroms, with about 10 angstroms being useful. Referencing FIGS. 4 and 10, and following resistive nucleation material 160 formation, bulk W deposition occurs via step 530 as described above. During bulk W deposition, WF6 is reduced by hydrogen gas. The thickness for the bulk W material 170 is variable depending on the device structure to be fabricated and is time dependent. Bulk W material can be from about 350 angstroms to about 450 angstroms on planar surfaces, and from about 2400 angstroms to about 2600 angstroms on non-planar surfaces.

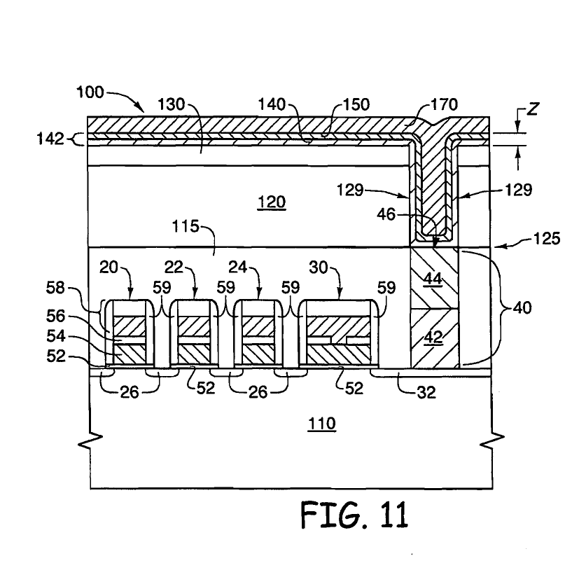

Referencing FIGS. 4 and 11, in another embodiment of the invention, following hydrogen plasma treatment (process step 400), in-process semiconductor 100 is removed from the plasma chamber and placed into a deposition chamber and subjected to the single substep W-CVD process 500 as described above. Here, bulk W is deposited during step 530 of process 500 without the necessity of depositing a resistive nucleation material via process substep 520. Tungsten denuded of nitride during hydrogen plasma treatment step 400 may be sufficient to promote subsequent W deposition allowing W to adhere to the substrate. The thickness for the bulk W material 170 is variable depending on the device structure to be fabricated but is similar to bulk W material thickness described above for two substep W-CVD process.

Once process flow according to embodiments of the present invention has occurred, further processing of semiconductor device 110 may be effected as known in the art, to fabricate complete semiconductor devices.

While this invention has been described with reference to illustrative embodiments, this description is not meant to be construed in a limiting sense. Various modifications and substitution of materials can be made without departing from the spirit or scope of the invention, and will be apparent to persons skilled in the art upon reference to this description. Accordingly, the above description and accompanying drawings are only illustrative of embodiments that can achieve the features and advantages of the present invention. It is not intended that the invention be limited to the embodiments shown and described in detail herein.

We claim:

1. A method of forming semiconductor interconnects comprising:
depositing a first conductive material by a deposition process on an in-process semiconducting substrate;
treating the first conductive material with a hydrogen plasma; and
depositing a second conductive material with a thermal chemical vapor deposition process following treating of first conductive material, wherein treating the first conductive material with the hydrogen plasma converts at least a portion of the first conductive material to a material capable of bonding to the second conductive material.

2. The method of claim 1, wherein the deposition process is an atomic layer deposition (ALD) process.

3. The method of claim 1, wherein the deposition process is a physical vapor deposition (CVD) process.

4. The method of claim 1, wherein the hydrogen treatment reduces about 10% to 100% of the first material.

5. The method of claim 1, wherein the hydrogen treatment reduces about 90% of the first material.

6. The method of claim 1, wherein the hydrogen treatment reduces about 100% of the first material.

7. The method of claim 1, wherein the first conductive material is tungsten nitride.

8. The method of claim 1, wherein the second conductive material is tungsten.

9. The method of claim 1, wherein the first material is both a barrier material and an adhesion material.

10. A method of depositing a tungsten material in semiconductor fabrication comprising:
exposing an in-process semiconductor substrate to an atomic layer deposition process comprising a first and second reactant and a nitridization reactant, wherein the first reactant comprises a boron- or silicon-containing material, the second reactant comprises a tungsten-containing material and the nitridization reactant comprises a nitrogen-containing material, forming an exposed tungsten nitride;
treating the exposed tungsten nitride with a hydrogen plasma, converting at least a portion of the tungsten nitride, creating an exposed tungsten outer material and leaving a thickness of tungsten nitride in contact with at least a portion of the in-process semiconductor substrate; and
exposing the exposed tungsten outer material to a thermal chemical vapor deposition process comprising a tungsten-fluoride containing compound, creating a bulk tungsten surface.

11. The method of claim 10, wherein the first reactant is selected from a group comprising diborane or silane.

12. The method of claim 10, wherein the first reactant is diborane.

13. The method of claim 10, wherein the second reactant is tungsten hexafluoride.

14. The method of claim 10, wherein the nitridization material is ammonia.

15. The method of claim 10, where the power source for the hydrogen plasma is selected from a group comprising radio frequency, microwave or remote plasma.

16. The method of claim 10, wherein the power source for the hydrogen plasma is radio frequency.

17. The method of claim 10, wherein the exposed tungsten nitride has a thickness of from about 10 to 60 angstroms.

18. The method of claim 10, wherein the exposed tungsten nitride has a thickness of from about 45 to 50 angstroms.

19. A method of forming tungsten interconnects during semiconductor fabrication comprising:
depositing a tungsten nitride material in a recessed region of a semiconductor substrate, the recessed region comprising a first and second sidewalk and a horizontal surface;
treating the tungsten nitride material with a hydrogen plasma to convert at least a portion of the tungsten nitride material to a tungsten material; and
depositing a tungsten layer adjacent to at least a portion of the converted tungsten nitride.

20. A method of forming a semiconductor interconnect comprising:
depositing a tungsten nitride material with an atomic layer deposition process on an in-process semiconducting substrate, the first material having a thickness of about less than or equal to 50 angstroms; and
treating the tungsten nitride material with a hydrogen plasma to convert at least a portion the tungsten nitride to tungsten.

21. A method of depositing tungsten without a resistive nucleation layer during semiconductor fabrication comprising:
converting at least a portion of a first material to tungsten by subjecting the first material to a hydrogen plasma; and
depositing a bulk tungsten material by a chemical vapor deposition process in contact with at least a portion of the converted first material.

22. The method of claim 21, wherein the first material is tungsten nitride.

23. A method of fabricating a conductive feature comprised of tungsten on an electronic device formed on a semiconductor substrate, comprising:
forming a recessed region within an in-process semiconductor, the recessed region comprising a first vertical sidewalk a second vertical sidewalk and a bottom horizontal surface;
depositing a tungsten nitride containing material at least within the recessed region;
subjecting the tungsten nitride containing material to a hydrogen plasma such that at least a portion of the tungsten nitride material is reduced to tungsten creating an exposed tungsten surface; and
depositing a tungsten material sufficient to fill the recessed region with tungsten.

24. The method of claim 23, wherein the recessed region is formed in alignment with a conductive element.

25. A method of fabricating a conductive feature comprised of tungsten on an electronic device formed on a semiconductor substrate, comprising:
depositing a tungsten nitride material in contact with at least a portion of an about planar surface of an electronic device;
subjecting the tungsten nitride material to a hydrogen plasma such that at least a portion of the tungsten nitride material is converted to a tungsten material creating an exposed tungsten surface; and
depositing additional tungsten material to contact the exposed tungsten-surface.

26. A conductive structure, comprising:
a tungsten nitride material in contact with at least a portion of an insulating material;
a tungsten material formed by converting at least a portion of the tungsten nitride material to tungsten by exposure to a hydrogen plasma; and
bulk tungsten in contact with at least a portion of the tungsten material converted from the tungsten nitride by exposure to the hydrogen plasma.
